(19) United States
(12) Patent Application Publication
(10) Pub. No.: US 2013/0327379 A1
(43) Pub. Date: Dec. 12, 2013

(54) CELL FOR REDUCING RECOMBINATION OF ELECTRONS AND HOLES AND METHOD FOR MANUFACTURING THE SAME

(71) Applicants: Wen-Chi Hou, Taipei Ctiy (TW); Tung-Hsien Wu, Taipei City (TW); Chih-Jui Ni, Taipei City (TW); Jyong-Sian Tsai, Taipei City (TW); Wen-Yi Tsai, Taipei City (TW); Chau-Nan Hong, Taipei City (TW)

(72) Inventors: Wen-Chi Hou, Taipei Ctiy (TW); Tung-Hsien Wu, Taipei City (TW); Chih-Jui Ni, Taipei City (TW); Jyong-Sian Tsai, Taipei City (TW); Wen-Yi Tsai, Taipei City (TW); Chau-Nan Hong, Taipei City (TW)

(73) Assignee: Bureau of Energy Ministry of Economic Affairs, Taipei City (TW)

(21) Appl. No.: 13/494,364

(22) Filed: Jun. 12, 2012

(51) Int. Cl. H01L 31/0236; H01L 31/18

(52) U.S. Cl. 136/255; 438/57; 257/E31.001

(57) ABSTRACT

A cell has a substrate, a first microstructure and an active layer. The first microstructure is formed on the substrate and has therein a first material with a concentration gradient toward one side of the substrate to provide a first built-in electric field. The active layer is mounted on the first microstructure so as to reduce recombination of electrons and holes in the cell.

### FIELD OF THE INVENTION

The invention relates to a cell and a method for manufacturing the same, and more particularly, to a cell for reducing recombination of electrons and holes and a method for manufacturing the same.

### BACKGROUND OF THE INVENTION

Recently, as daily energy sources, e.g. petroleum, coal and natural gas, are about to be exhausted due to over exploitation of the same, focuses on alternative energy sources for replacing these daily ones are increasingly concerned by the public. Among alternative energy sources, solar cells converting solar energy into electric energy have become the primary target for solving the urgent problems.

A conventional solar cell, from bottom to top, is composed of a substrate, a first electrode, an active layer and a second electrode. When incident light is irradiated into the solar cell, electrons and holes in the active layer are generated, the generated electrons and holes are dissociated due to the concentration gradient or built-in electric field in the active layer, and thus photocurrent is formed. Then when a load or an electronic device is connected to the two electrodes of the solar cell, electric energy will be supplied to drive the load or the electronic device.

However, when the electrons and the holes in the active layer are separated, these electrons and holes tend to recombination inside the active layer, or at an interface between the active layer and any of the two electrodes. With such a recombination tendency, the electrons and the holes are combined with each other again and heat is generated, which causes the electrons and the holes incapable of moving toward the two electrodes respectively. In other words, recombination of electrons and holes results in converting solar energy into heat though, it also reduces the formation of photocurrent and the electric energy supplied to drive the load or the electronic device.

### SUMMARY OF THE INVENTION

In one aspect, a novel cell is provided, and the cell has a substrate and comprises a first microstructure and an active layer. The first microstructure is formed on the substrate and has therein a first material with a concentration gradient toward one side of the substrate to provide a first built-in electric field. The active layer is mounted on the first microstructure so as to reduce recombination of electrons and holes in the cell.

In another aspect, a method for manufacturing a cell is provided in the invention, and the method comprises: forming a first microstructure on a substrate, the first microstructure having therein a first material with a concentration gradient toward one side of the substrate to provide a first built-in electric field; and forming an active layer on the first microstructure so as to reduce recombination of electrons and holes in the cell.

### BRIEF DESCRIPTION OF THE DRAWINGS

FIG. 1 is a cross-section view of a cell according to a preferred embodiment of the invention.

FIGS. 2A to 2C illustrate a method for manufacturing a cell according to the invention.

### DETAILED DESCRIPTION OF THE INVENTION

Other features and advantages of the invention will become apparent in the following detailed description of a preferred embodiment with reference to the accompanying drawings.

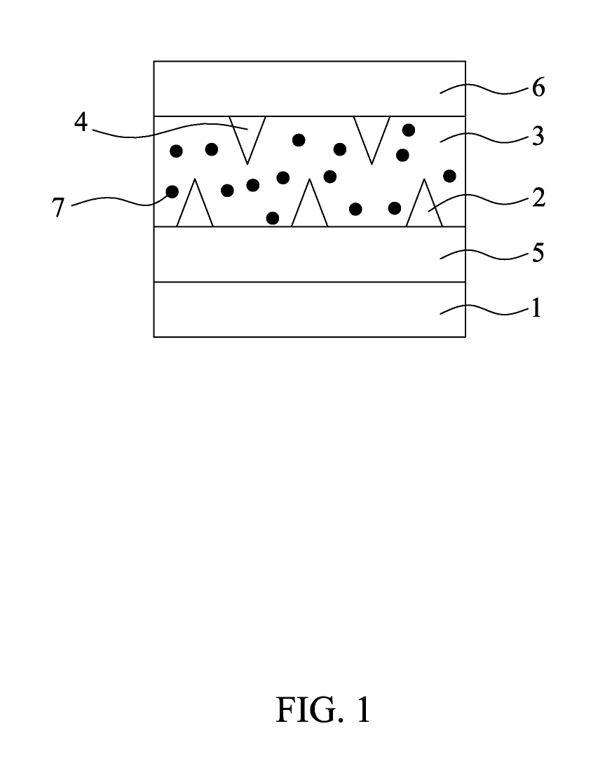

Referring to FIG. 1, a cell according to one embodiment of the invention is presented. The cell, namely a solar cell, comprises a substrate 1, a first microstructure 2 and an active layer 3.

The substrate 1 has a top side and a bottom side opposite to the top side. The substrate 1 may be a transparent substrate such as a glass substrate.

The first microstructure 2 is formed on the top side of the substrate 1 and extended in a direction, and has therein a first material with a concentration gradient toward the top side of the substrate 1 to provide a first built-in electric field. The first microstructure 2 may be made of a material selected from a group consisting of monocrystalline silicon, III-V compound semiconductor and II-VI compound semiconductor, and may be in a shape of a wire, a cone or a pillar.

The first material may be a p-type doped material or an n-type doped material. Specifically, the first microstructure 2 is p-type doped when the first material is a p-type doped material, and the first microstructure 2 is n-type doped when the first material is an n-type doped material.

Besides, the first material in the first microstructure 2 may have a concentration increasing toward the top side of the substrate 1 to provide the first built-in electric field.

The active layer 3 is employed for converting light into electron-hole pairs in the cell and mounted on the first microstructure 2. The active layer 3 may be made of a material selected from a group consisting of organic compound, copper indium gallium selenide (CIGS), copper indium selenide (CIS), cadmium tellurium (CdTe) and dye-sensitized compound. In detail, when incident light is irradiated into the cell, electrons and holes in the active layer 3 are generated, and then dissociated. Because the first built-in electric field is formed in the cell by the first material of the first microstructure 2, these dissociated electrons and holes in the active layer 3 are attracted to two opposite sides of the active layer 3 respectively, such that recombination of these dissociated electrons and holes in the active layer 3 is reduced, and then a photocurrent is increasingly formed.

When the first material in the first microstructure 2 is a p-type doped material and has a concentration increasing toward the top side of the substrate 1, the provided first built-in electric field allows an electric field direction opposite to the direction which the first microstructure 2 is extended in. With the electric field direction, the separated electrons are attracted to a location opposite to the top side of the substrate 1, and the separated holes are attracted toward the top side of the substrate 1, so that these dissociated electrons and holes in the active layer 3 are moved to two opposite sides of the active layer 3 respectively.

When the first material in the first microstructure 2 is an n-type doped material and has a concentration increasing toward the top side of the substrate 1, the provided first built-in electric field allows an electric field direction parallel to the direction which the first microstructure 2 is extended in. With the electric field direction, the separated electrons are attracted toward the top side of the substrate 1, and the separated holes are attracted to a location opposite to the top side of the substrate 1, so that these dissociated electrons and holes in the active layer 3 are moved to two opposite sides of the active layer 3 respectively.

Next, the cell further comprises a second microstructure 4 which is formed on the active layer 3 and has therein a second material with a concentration gradient toward one side of the active layer 3 to provide a second built-in electric field. The second microstructure 4 may be made of a material selected from a group consisting of monocrystalline silicon, III-V compound semiconductor and II-VI compound semiconductor and may be in a shape of a wire, a cone or a pillar.

The second material may be a p-type doped material or an n-type doped material. Specifically, the second microstructure 4 is p-type doped when the second material is a p-type doped material, and the second microstructure 4 is n-type doped when the second material is an n-type doped material. Further, the second microstructure 4 is opposite to the first microstructure 2. That is to say, when the second microstructure 4 is p-type doped, the first microstructure 2 is n-type doped, and vice versa.

Resulting from the first built-in electric field formed in the cell by the first material of the first microstructure 2 and the second built-in electric field formed in the cell by the second material of the second microstructure 4, the dissociated electrons and holes in the active layer 3 are attracted to two opposite sides of the active layer 3 respectively. In such a way, recombination of the dissociated electrons and holes in the active layer 3 is reduced, and a photocurrent is then increasingly formed.

Likewise, the second material in the second microstructure 4 may be with a concentration increasing opposite to the side of the active layer 3 to provide the second built-in electric field. When the first material in the first microstructure 2 is a p-type doped material and has a concentration increasing toward the top side of the substrate 1, and the second material in the second microstructure 4 is an n-type doped material and has a concentration increasing opposite to the side of the active layer 3, the provided first built-in electric field and second built-in electric field allow an electric field direction to be opposite to the direction that the first microstructure 2 is extended in. With the electric field direction, the separated electrons are attracted to a location opposite to the top side of the substrate 1, and the separated holes are attracted toward the top side of the substrate 1, such that the dissociated electrons and holes in the active layer 3 are moved to two opposite sides of the active layer 3 respectively.

When the first material in the first microstructure 2 is an n-type doped material and has a concentration increasing toward the top side of the substrate 1, and the second material in the second microstructure 4 is a p-type doped material and has a concentration increasing opposite to the side of the active layer 3, the provided first built-in electric field and second built-in electric field allow an electric field direction to be parallel to the direction that the first microstructure 2 is extended in. With the electric field direction, the separated electrons are attracted toward the top side of the substrate 1, and the separated holes are attracted to a location opposite to the top side of the substrate 1, such that the dissociated electrons and holes in the active layer 3 are moved to two opposite sides of the active layer 3 respectively.

Next, the cell further comprises a bottom electrode 5 which is formed between the substrate 1 and the first microstructure 2. The bottom electrode 5 may be a transparent electrode made of a material selected from a group consisting of zinc oxide, tin oxide, indium tin oxide (ITO), indium tin zinc oxide (ITZO), aluminum tin oxide (ATO), aluminum zinc oxide (AZO), cadmium indium oxide (CIO), cadmium zinc oxide (CZO), gallium zinc oxide (GaZO) and tin oxyfluoride.

Next, the cell further comprises a top electrode 6 which is formed on the active layer 3 to be electrically connected to the bottom electrode 5. The top electrode 6 may be a transparent electrode which is made of a material described with reference to the bottom electrode 5, so no further description is made. When incident light is irradiated into the cell, electrons and holes in the active layer 3 are dissociated and conducted to the bottom electrode 5 and the top electrode 6 respectively to form a photocurrent.

Next, the cell further comprises quantum dots 7 which is formed in the active layer 3 for light absorption. Specifically, with these quantum dots 7, when incident light is irradiated to the cell, more incident light is absorbed by the cell, and then more electrons and more holes in the active layer 3 are dissociated. This results in the increase of photocurrent forming

Hereinafter, a method for manufacturing a cell of the invention is provided.

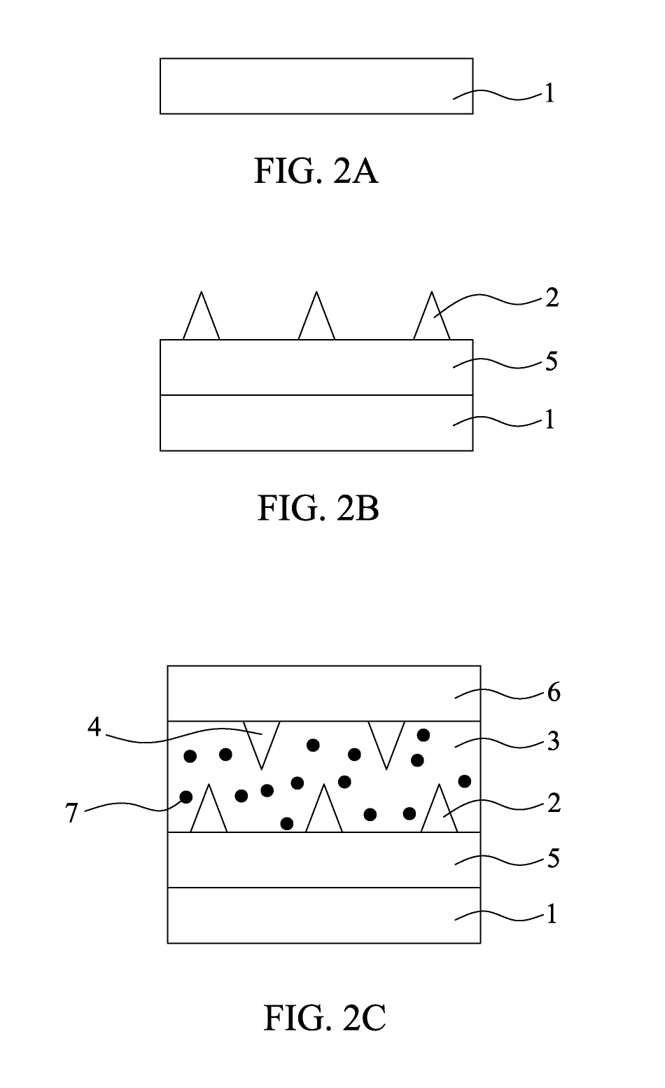

As shown in FIG. 2A, a substrate 1 is provided and has a top side and a bottom side opposite to the top side.

As shown in FIG. 2B, a first microstructure 2 is formed on the top side of the substrate 1 and has therein a first material with a concentration gradient toward the top side of the substrate 1 to provide a first built-in electric field via the following methods. In the first method, firstly a layer is formed on the top side of the substrate 1 via, for example, a coating process, an evaporation deposition process or an electroplating process. Secondly the layer is etched to form the first microstructure 2. Finally the first material is doped into the first microstructure 2 via, for example, a thermal diffusion process. In the second method, the first microstructure 2 is formed via an evaporation deposition process, and different concentration of the first material is doped into the first microstructure 2 at the different time frames of the evaporation deposition process.

As known from the above description, the first material in the first microstructure 2 may have a concentration increasing toward the top side of the substrate 1 to provide the first built-in electric field. It shall be emphasized that according to the knowledge in the art, such features are done via the two methods, so no further description is made.

As shown in FIG. 2C, an active layer 3 is formed on the first microstructure 2 so as to reduce recombination of electrons and holes in the cell via, for example, a spin coating process, a dip coating process, a casting process or a thermal evaporation process.

In one aspect, as shown in FIG. 2C, after forming the active layer 3, a second microstructure 4 is formed on the active layer 3 and has therein a second material with a concentration gradient toward a side of the active layer 3 to provide a second built-in electric field via methods which are similar to the methods for the first microstructure 2.

In another aspect, as shown in FIG. 2B, after providing the substrate 1 and before forming the first microstructure 2, a bottom electrode 5 is formed between the substrate 1 and the first microstructure 2 via, for example, a coating process, an evaporation deposition process or an electroplating process; further, as shown in FIG. 2C, after forming the active layer 3, a top electrode 6 is formed on the active layer 3 to be electrically connected to the bottom electrode 5 via, for example, a coating process, an evaporation deposition process or an electroplating process.

In further aspect, as shown in FIG. 2C, after forming the active layer 3, quantum dots 7 are formed in the active layer 3 for light absorption.

Finally, as what is described above, through the deposition that the first microstructure has therein a first material with a concentration gradient toward one side of the substrate to provide a first built-in electric field, and the active layer is mounted on the first microstructure, the first built-in electric field of the first microstructure forms an electric field direction in the cell so that recombination of electrons and holes in the cell when incident light is irradiated into the cell.

While the invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

What is claimed is:

1. A cell having a substrate and comprising:
a first microstructure formed on the substrate and having therein a first material with a concentration gradient toward one side of the substrate to provide a first built-in electric field; and
an active layer mounted on the first microstructure so as to reduce recombination of electrons and holes in the cell.

2. The cell as claimed in claim 1 further comprising a second microstructure formed on the active layer, the second microstructure having therein a second material with a concentration gradient toward one side of the active layer to provide a second built-in electric field.

3. The cell as claimed in claim 1, wherein the active layer is made of a material selected from a group consisting of organic compound, copper indium gallium selenide, copper indium selenide, cadmium-tellurium and dye-sensitized compound.

4. The cell as claimed in claim 2, wherein the second microstructure is opposite to the first microstructure.

5. The cell as claimed in claim 1, wherein the first microstructure is in a shape of a wire, a cone or a pillar.

6. The cell as claimed in claim 2, wherein the second microstructure is in a shape of a wire, a cone or a pillar.

7. The cell as claimed in claim 1, wherein the first microstructure is made of a material selected from a group consisting of monocrystalline silicon, III-V compound semiconductor and II-VI compound semiconductor.

8. The cell as claimed in claim 2, wherein the second microstructure is made of a material selected from a group consisting of monocrystalline silicon, III-V compound semiconductor and II-VI compound semiconductor.

9. The cell as claimed in claim 1, wherein the first material is a p-type doped material or an n-type doped material.

10. The cell as claimed in claim 2, wherein the second material is a p-type doped material or an n-type doped material.

11. The cell as claimed in claim 2, wherein the first material is a p-type doped material and the second material is an n-type doped material.

12. The cell as claimed in claim 2, wherein the first material is an n-type doped material and the second material is a p-type doped material.

13. The cell as claimed in claim 1 further comprising a bottom electrode formed between the substrate and the first microstructure.

14. The cell as claimed in claim 13 further comprising a top electrode formed on the active layer.

15. The cell as claimed in claim 2 further comprising a bottom electrode formed between the substrate and the first microstructure.

16. The cell as claimed in claim 15 further comprising a top electrode formed on the active layer.

17. The cell as claimed in claim 1 further comprising quantum dots in the active layer for light absorption.

18. A method for manufacturing a cell, comprising:
forming a first microstructure on a substrate, the first microstructure having therein a first material with a concentration gradient toward one side of the substrate to provide a first built-in electric field; and
forming an active layer on the first microstructure so as to reduce recombination of electrons and holes in the cell.

19. The method as claimed in claim 18 further comprising forming a second microstructure on the active layer, the second microstructure having therein a second material with a concentration gradient toward one side of the active layer to provide a second built-in electric field after the active layer forming step.

20. The method as claimed in claim 18 further comprising forming quantum dots in the active layer for light absorption after the active layer forming step.
